(19) United States
(12) Patent Application Publication
(10) Pub. No.: US 2019/0348471 A1
(43) Pub. Date: Nov. 14, 2019

(54) FULL COLOR DISPLAY DEVICE AND MANUFACTURING METHOD THEREOF

(71) Applicant: Wuhan China Star Optoelectronics Semiconductor Display Technology Co., Ltd., Wuhan (CN)

(72) Inventors: Jing Huang, Shenzhen (CN); Hsiang-lun Hsu, Shenzhen (CN)

(21) Appl. No.: 16/247,535

(22) Filed: Jan. 14, 2019

Related U.S. Application Data
(63) Continuation of application No. PCT/CN2018/096504, filed on Jul. 20, 2018.

(30) Foreign Application Priority Data
May 11, 2018 (CN) 201810446501.0

(51) Int. Cl. H01L 27/32; H01L 51/56; H01L 51/50; H01L 51/52

(52) U.S. Cl. CPC H01L 27/322; H01L 51/56; H01L 2251/5376; H01L 51/5253; H01L 51/5036

(57) ABSTRACT

The present disclosure discloses a full color display device and a manufacturing method thereof. The full color display device includes a first electrode layer formed on a first substrate; an light emitting layer formed on the first electrode layer, wherein the light emitting layer includes a first light emitting layer and a second light emitting layer disposed at intervals, the first light emitting layer includes luminescent materials of a first color and a second color, the second light emitting layer includes a luminescent material of a third color, and the first color, the second color, and the third color constitute three primary colors; a second electrode layer formed on the light emitting layer; and a color filter layer formed on the second electrode layer at a position corresponding to the first light emitting layer. The present disclosure can realize full color display and improve the display rate of the panel.

### CROSS-REFERENCE TO RELATED APPLICATIONS

The present application is a continuation-application of International (PCT) Patent Application No. PCT/CN2018/096504 filed on Jul. 20, 2018, which claims foreign priority of Chinese Patent Application No. 201810446501.0, filed on May 11, 2018 in the State Intellectual Property Office of China, the entire contents of which are hereby incorporated by reference.

### TECHNICAL FIELD

The present application relates to the field of display technology, and in particular to a full color display device and a manufacturing method thereof.

### BACKGROUND

Organic light-emitting diodes (OLED) are known as the third-generation display technology after cathode ray tubes (CRT), liquid crystal displays (LCD) and light-emitting diodes (LED) because of their fast response, wide temperature range, self-luminescence, and flexible display.

With the increasing market demand, the development and production of flexible OLEDs has become a hot field in the display industry. Due to the increasing market demand for panel resolution, how to improve the panel resolution is still the bottleneck of the current process. Among them, the precision metal mask is used in the traditional process technology, and the mass production process requires 5 to 6 process steps, which is costly. In addition, in the traditional process, white light pulsing color photoresist is used to realize full color display, but because of its low efficiency and the device needs to adopt a stacked structure, the driving voltage of the device is further increased, thereby reducing the power consumption of the device.

### SUMMARY

The present disclosure provides a full color display device and a manufacturing method thereof, which can realize full color display and improve the display rate of the panel.

In order to solve the above technical problem, a technical solution adopted by the present disclosure is to provide a full color display device. The full color display device includes: a first electrode layer formed on a first substrate; an light emitting layer formed on the first electrode layer, wherein the light emitting layer includes a first light emitting layer and a second light emitting layer disposed at intervals, the first light emitting layer includes luminescent materials of a first color and a second color, the second light emitting layer includes a luminescent material of a third color, the first color, the second color, and the third color constitute three primary colors, and the luminescent materials are one of a fluorescent luminescent material or a phosphorescent luminescent material; a second electrode layer formed on the light emitting layer; and a color filter layer formed on the second electrode layer at a position corresponding to the first light emitting layer, wherein the color filter layer includes a first filter layer and a second filter layer disposed at intervals, and the first filter layer and the second filter layer correspond to the colors of the luminescent materials of the first light emitting layer; wherein, the full color display device further includes an encapsulation layer arranged on the second electrode layer.

In order to solve the above technical problem, another technical solution adopted by the present disclosure is to provide a full color display device. The full color display device includes: a first electrode layer formed on a first substrate; an light emitting layer formed on the first electrode layer, wherein the light emitting layer includes a first light emitting layer and a second light emitting layer disposed at intervals, the first light emitting layer includes luminescent materials of a first color and a second color, the second light emitting layer includes a luminescent material of a third color, and the first color, the second color, and the third color constitute three primary colors; a second electrode layer formed on the light emitting layer; and a color filter layer formed on the second electrode layer at a position corresponding to the first light emitting layer, wherein the color filter layer includes a first filter layer and a second filter layer disposed at intervals, and the first filter layer and the second filter layer correspond to the colors of the luminescent materials of the first light emitting layer.

In order to solve the above technical problem, another technical solution adopted by the present disclosure is to provide a manufacturing method of a full color display device. The manufacturing method of a full color display device includes: forming a first electrode layer on the first substrate; forming a light emitting layer including a first light emitting layer and a second light emitting layer on the first electrode layer, wherein the first light emitting layer includes luminescent materials of a first color and a second color, the second light emitting layer includes a luminescent material of a third color, and the first color, the second color, and the third color constitute three primary colors; forming a second electrode layer on the light emitting layer; and forming a color filter layer on the second electrode layer at a position corresponding to the first light emitting layer, wherein the color filter layer includes a first filter layer and a second filter layer disposed at intervals, and the first filter layer and the second filter layer correspond to colors of the luminescent materials of the first light emitting layer.

The present disclosure has the beneficial effects of providing a full color display device and a manufacturing method thereof, and by using luminescent materials of any two colors of three primary colors to form a single two-color light emitting device, the corresponding organic layer can emit a light source of the corresponding color. Further, combined with the corresponding color filter layer and combined with a monochrome display device, full color display can be realized, and the display rate of the panel is further improved.

### BRIEF DESCRIPTION OF THE DRAWINGS

In order to make the technical solution described in the embodiments of the present disclosure more clear, the drawings used for the description of the embodiments will be briefly described. Apparently, the drawings described below are only for illustration but not for limitation. It should be understood that, one skilled in the art may acquire other drawings based on these drawings, without making any inventive work.

FIG. 1 is a schematic structural diagram of a first embodiment of a full color display device of the present disclosure.

FIG. 2 is a schematic structural diagram of a second embodiment of a full color display device of the present disclosure.

FIG. 3 is a schematic structural diagram of a third embodiment of a full color display device of the present disclosure.

FIG. 4 is a schematic flow chart of a first embodiment of a manufacturing method of a full color display device of the present disclosure.

FIG. 5 is a schematic flow chart of a second embodiment of a manufacturing method of a full color display device of the present disclosure.

### DETAILED DESCRIPTION

The technical solutions in the embodiments of the present application are clearly and completely described below with reference to the accompanying drawings in the embodiments of the present application. Apparently, the described embodiments are merely a part but not all of the embodiments of the present application. All other embodiments obtained by a person of ordinary skill in the art based on the embodiments of the present invention without creative efforts shall fall within the protection scope of the present invention.

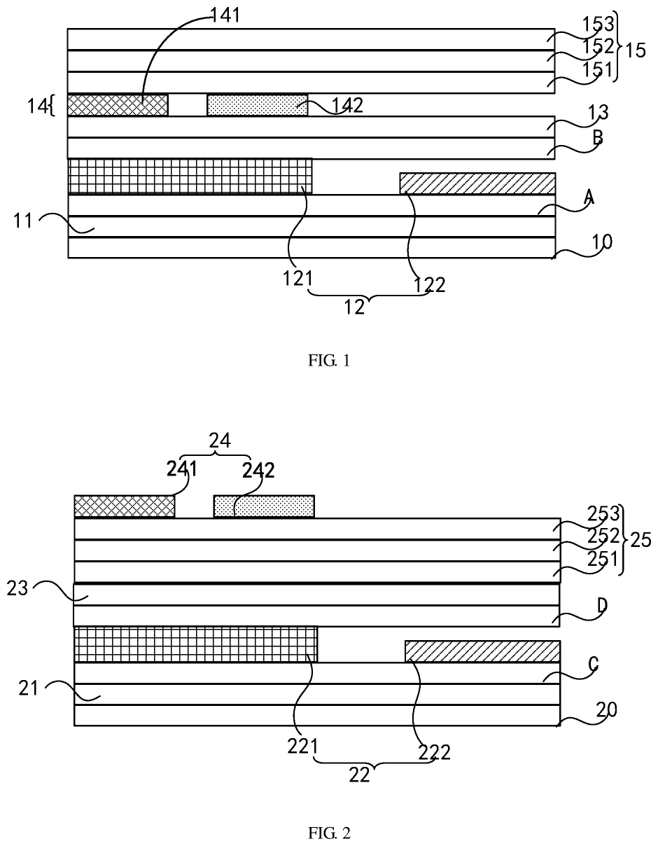

Please referring to FIG. 1, FIG. 1 is a schematic structural diagram of a first embodiment of a full color display device of the present disclosure. As shown in FIG. 1, the full color display device of the present disclosure may include a first substrate 10, a first electrode layer 11, a light emitting layer 12, a second electrode layer 13, and a color filter layer 14.

The first electrode layer 11 may be formed on the first substrate 10. The material of first substrate 10 may be a transparent one, such as glass, ceramic substrate or transparent plastic. The first substrate 10 may further include at least one thin film transistor (TFT) and a first common organic layer A formed on the first electrode layer 11, and the first common organic layer A may include a hole injection layer and a hole transport layer (not shown).

The light emitting layer 12 may be formed on the first electrode layer 11. In the present embodiment, the light emitting layer 12 may be formed on the first common organic layer A and may include a first light emitting layer 121 and a second light emitting layer 122.

The first light emitting layer 121 may include luminescent materials of a first color and a second color, and the second light emitting layer 122 may include a luminescent material of a third color. In the present disclosure, the first color, the second color, and the third color may constitute three primary colors. That is, in a specific embodiment, the first light emitting layer 121 may be composed of a red luminescent material and a blue one, or a blue luminescent material and a green one, or a red luminescent material and a green one. The second light emitting layer 122 can be composed of a green luminescent material, a red one or a blue one. It can be understood that the terms first color, second color and third color in the present disclosure are only for distinguishing that the light emitting layer is composed of luminescent materials of different colors, and the light emitting layer is not further limited.

That is to say, in the first light emitting layer 121 of the present disclosure, luminescent materials of any two of the three primary colors are used to form a single two-color light emitting device, so that the corresponding organic layer can emit a light source of a corresponding color. In the actual process, the preparation of a fine metal mask (FMM) can be reduced compared to the conventional RGB device, which may save the process flow.

For example, in the present embodiment, the first light emitting layer 121 may be a single two-color light emitting device composed of a red luminescent material and a blue one, and the second light emitting layer 122 is a monochromatic light emitting device composed of a green one. In the present embodiment, the blue luminescent material and the green one may be a fluorescent luminescent material or a phosphorescent one, and the red luminescent material is a phosphorescent one.

The second electrode layer 13 may be formed above the light emitting layer 12, and the full color display device of the present disclosure may further include a second common organic layer B. The second common organic layer B may be formed between the light emitting layer 12 and the second electrode layer 13, and specifically may include an electron transport layer and an electron injection layer (not shown).

The color filter layer 14 may be formed on the second electrode layer 13 at a position corresponding to the first light emitting layer 121. In the present embodiment, the color filter layer 14 may be directly formed on the second electrode layer 13. The color filter layer 14 may include a first filter layer 141 and a second filter layer 142 which are disposed at intervals. The first filter layer 141 and the second filter layer 142 correspond to the color of the luminescent material of the first light emitting layer 121. In the present embodiment, the first light emitting layer 121 may be composed of a red luminescent material and a blue one. The color of the first filter layer 141 in the color filter layer 14 may be a blue filter layer or a red one. The selection of its specific color may be based on the selection of the color of the luminescent material in the first light emitting layer 121. In the present embodiment, compared with the white color plus color filter layer in the conventional full color display device, only two-color filter layers are needed in the present disclosure, thereby reducing the process of one-color filter layer.

In another embodiment, the full color display device in the present disclosure may further include an encapsulation layer 15 formed on the second electrode layer 13. The encapsulation layer 15 may be formed on the color filter layer 14. The first encapsulation layer 151, the second encapsulation layer 152, and the third encapsulation layer 153 may also be included for blocking the external water oxygen from eroding the light emitting device. The first encapsulation layer 151 and the third encapsulation layer 153 may be an inorganic layer structure, and the second encapsulation layer 152 may be an organic layer structure.

In the present embodiment, the luminescent material of any two colors of the three primary colors is used to form a single two-color light emitting device, so that the corresponding organic layer can emit a light source of a corresponding color. Further, combined with the corresponding color filter layer and combined with a monochrome display device, a full color display can be realized. Further, the two-color light emitting device can reduce the use of a fine metal mask and reduce a color film process. In addition, the two-color light emitting device is used, the driving voltage can be half that of a conventional display device.

Of course, in other embodiments, the first light emitting layer 121 may also be composed of a blue luminescent material and a green one or a red luminescent material and a green one, the second light emitting layer 122 may be composed of a red luminescent material or a blue one, and the principle thereof is similar to the illuminating principle in the present embodiment, and details are not described herein again.

In the above embodiment, by using luminescent materials of any two of the three primary colors to form a single two-color light emitting device, the corresponding organic layer can emit a light source of a corresponding color. Further, combined with the corresponding color filter layer and combined with a monochrome display device, a full color display can be realized, and the display rate of the panel is further improved.

Please referring to FIG. 2, FIG. 2 is a schematic structural diagram of a second embodiment of a full color display device of the present disclosure. The full color display device in the second embodiment has substantially the same structure as the full color display device in the first embodiment. The difference is that the color filter layer in the second embodiment is formed on the encapsulation layer, and the details are not described again. The specific description is as follows:

The full color display device of the present disclosure may include a first electrode layer 21, a light emitting layer 22, a second electrode layer 23, a color filter layer 24, and an encapsulation layer 25.

The first electrode layer 21 may be formed on the first substrate 20, The first substrate 20 may further include at least one thin film transistor (TFT) on the first substrate 20 and a first common organic layer C formed on the first electrode layer 21. The first common organic layer C may include a hole injection layer and a hole transport layer.

The light emitting layer 22 may be formed on the first electrode layer 21. In the present embodiment, the light emitting layer 22 may be formed on the first common organic layer C and may include a first light emitting layer 221 and a second light emitting layer 222.

The first light emitting layer 221 may include luminescent materials of a first color and a second color, and the second light emitting layer 222 may include a luminescent material of a third color. In the present disclosure, the first color, the second color, and the third color may constitute three primary colors. In the present embodiment, the first light emitting layer 221 may be a single two-color light emitting device and may be composed of a red luminescent material and a blue one. The second light emitting layer 222 may be a monochromatic light emitting device and may be composed of a green luminescent material.

The second electrode layer 23 may be formed on the light emitting layer 22, and the full color display device in the present disclosure may further include a second common organic layer D. The second common organic layer D may be formed between the light emitting layer 22 and the second electrode layer 23, and may specifically include an electron transport layer and an electron injection layer.

The encapsulation layer 25 may be directly formed on the second electrode layer 23, and may include a first encapsulation layer 251, a second encapsulation layer 252, and a third encapsulation layer 253 for blocking external water and oxygen from eroding the light emitting device. The first encapsulation layer 251 and the third encapsulation layer 253 may be an inorganic layer structure, and the second encapsulation layer 252 may be an organic layer structure.

The color filter layer 24 may be formed on the encapsulation layer 25 at a position corresponding to the first light emitting layer 221 and may include a first filter layer 241 and a second filter layer 242 disposed at intervals. The first filter layer 241 and the second filter layer 242 correspond to the color of the first light emitting layer 221 luminescent material. In the present embodiment, the first light emitting layer 221 may be composed of a red luminescent material and a blue one. The color of the first filter layer 241 in the color filter layer 24 may be a blue filter layer or a red one. The selection of its specific color may be based on the selection of the color of the luminescent material in the first light emitting layer 221.

In the above embodiment, by using luminescent materials of any two of the three primary colors to form a single two-color light emitting device, the corresponding organic layer can emit a light source of a corresponding color. Further, combined with the corresponding color filter layer and combined with a monochrome display device, a full color display can be realized, and the display rate of the panel is further improved.

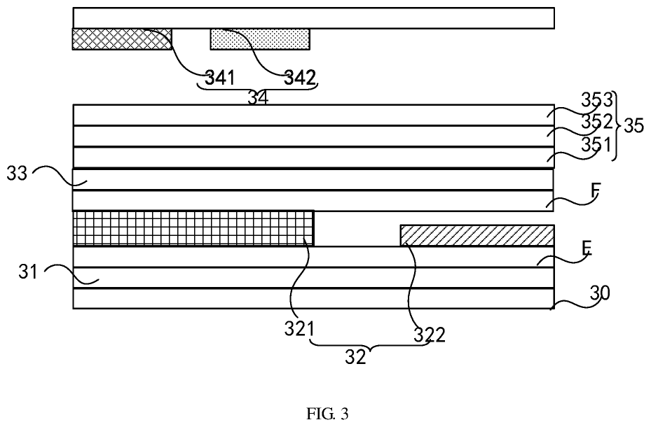

Please referring to FIG. 3, FIG. 3 is a schematic structural diagram of a third embodiment of a full color display device of the present disclosure. The full color display device in the third embodiment has substantially the same structure as the full color display device in the first embodiment. The difference may be that the color filter layer in the third embodiment may be formed on the second substrate, and the details are not described again, and the details are as follows:

The full color display device of the present disclosure may include a first electrode layer 31, a light emitting layer 32, a second electrode layer 33, a color filter layer 34, an encapsulation layer 35, and a second substrate 36.

The first electrode layer 31 may be formed on the first substrate 30. The first substrate 30 may further include at least one thin film transistor (TFT) and a first common organic layer E formed on the first electrode layer 31, and the first common organic layer E may include a hole injection layer and a hole transport layer.

The light emitting layer 32 may be formed on the first electrode layer 31. In the present embodiment, the light emitting layer 32 may be formed on the first common organic layer E and may include a first light emitting layer 321 and a second light emitting layer 322. The first light emitting layer 321 may include luminescent materials of a first color and a second color, and the second light emitting layer 322 may include a luminescent material of a third color. In the present disclosure, the first color, the second color, and the third color may constitute three primary colors. In the present embodiment, the first light emitting layer 321 may be a single two-color light emitting device and may be composed of a red luminescent material and a blue one. The second light emitting layer 322 may be a monochromatic light emitting device and may be composed of a green luminescent material.

The second electrode layer 33 may be formed on the light emitting layer 32, and the full color display device in the present disclosure may further include a second common organic layer F. The second common organic layer F may be formed between the light emitting layer 32 and the second electrode layer 33, and may specifically include an electron transport layer and an electron injection layer.

The encapsulation layer 35 may be directly formed on the second electrode layer 33, and may include a first encapsulation layer 351, a second encapsulation layer 352, and a third encapsulation layer 353 for blocking external water and oxygen from eroding the light emitting device. The first encapsulation layer 351 and the third encapsulation layer 353 may be an inorganic layer structure, and the second encapsulation layer 352 may be an organic layer structure.

The second substrate 36 may be formed on the encapsulation layer 35.

The color filter layer 34 may be formed on the second substrate 36 and may include a first filter layer 341 and a second filter layer 342 disposed at intervals. The first filter layer 341 and the second filter layer 342 correspond to the color of the luminescent material of the first light emitting layer 321. In the present embodiment, the first light emitting layer 321 may be composed of a red luminescent material and a blue one. The color of the first filter layer 341 in the color filter layer 34 may be a blue filter layer or a red one. The selection of its specific color may be based on the selection of the color of the luminescent material in the first light emitting layer 321.

In the above embodiment, by using luminescent materials of any two of the three primary colors to form a single two-color light emitting device, the corresponding organic layer can emit a light source of a corresponding color. Further, combined with the corresponding color filter layer and combined with a monochrome display device, a full color display can be realized, and the display rate of the panel is further improved.

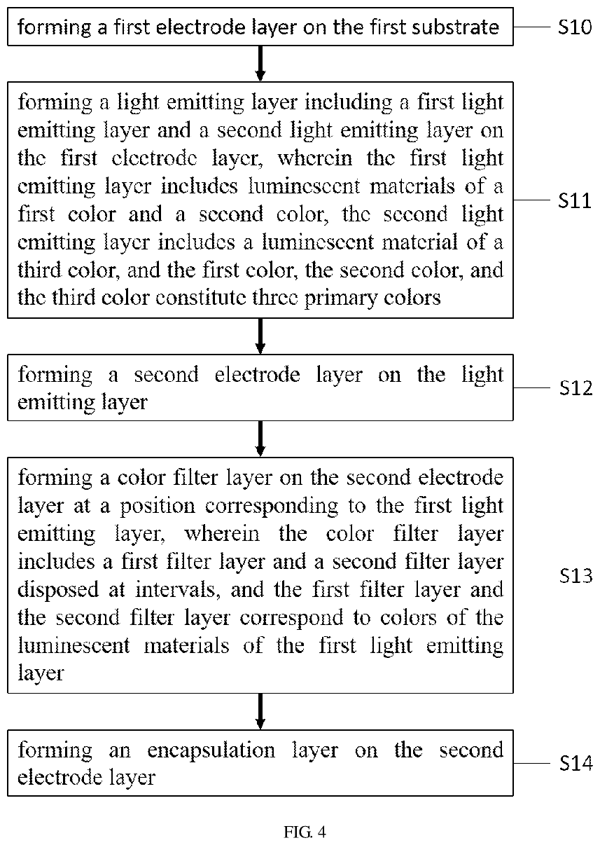

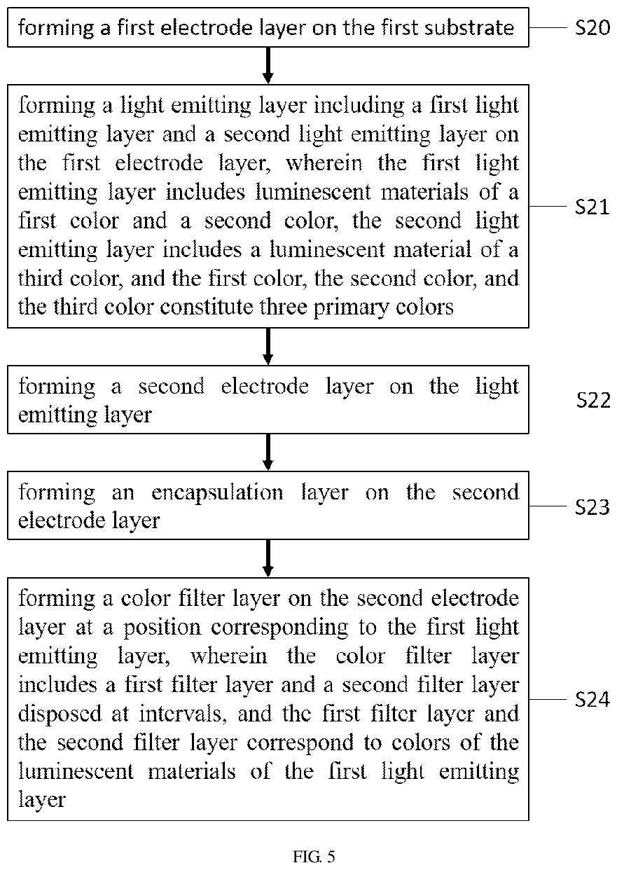

Please referring to FIG. 4. FIG. 4 is a schematic flow chart of a first embodiment of a manufacturing method of a full color display device of the present disclosure. Specific blocks are as follows:

S10, forming a first electrode layer on the first substrate.

The first substrate may be a transparent material and may be any substrate of any form such as glass, ceramic substrate or transparent plastic. Further, a first electrode layer and a first common organic layer may be sequentially formed on the first substrate. Wherein, the first common organic layer may include a hole injection layer and a hole transport layer.

S11, forming a light emitting layer including a first light emitting layer and a second light emitting layer on the first electrode layer, wherein the first light emitting layer may include luminescent materials of a first color and a second color, the second light emitting layer may include a luminescent material of a third color, and the first color, the second color, and the third color constitute three primary colors.

The specific details of block S11 is described in detail in the first to third embodiments of the above-described full color display device, and are not described herein again.

S12, forming a second electrode layer on the light emitting layer.

Before forming the second electrode layer, it is necessary to prepare a second common organic layer on the light emitting layer, including an electron transport layer and an electron injection layer, and then forming the second electrode layer on the second common organic layer.

S13, forming a color filter layer on the second electrode layer at a position corresponding to the first light emitting layer, wherein the color filter layer may include a first filter layer and a second filter layer disposed at intervals, and the first filter layer and the second filter layer correspond to colors of the luminescent materials of the first light emitting layer.

The position of the color filter layer in the present disclosure can be divided into the following three cases:

1. the color filter layer may be formed between the second electrode layer and the encapsulation layer.

2. the color filter layer may be formed on the encapsulation layer.

3. the color filter layer may be formed on the second substrate.

For detailed description of the position setting and the color of the color filter layer, a detailed description of the first to third embodiments of the full color display device will be described in detail, and the details of which are not described herein again.

The manufacturing method of the full color display device of the present disclosure may further include:

S14, forming an encapsulation layer on the second electrode layer.

The block S14 may also be before the block S13, or may be after the block S13, and the specific position of the block needs to refer to the specific position of the color filter layer. In an embodiment, if the color filter layer is formed between the second electrode layer forming and encapsulation layers, the block S14 may be after step S13, seeing FIG. 4. If the color filter layer is formed on the encapsulation layer or on the second substrate, the block S14 is before block S13, seeing FIG. 5. For the specific configuration and material selection of the encapsulation layer, please refer to the detailed description of the first to third embodiments of the full color display device, and details are not described herein again.

In the above embodiment, by using luminescent materials of any two of the three primary colors to form a single two-color light emitting device, the corresponding organic layer can emit a light source of a corresponding color. Further, combined with the corresponding color filter layer and combined with a monochrome display device, a full color display can be realized, and the display rate of the panel is further improved.

In summary, those skilled in the art will readily understand that the present disclosure provides a full color display device and a manufacturing method thereof. By using luminescent materials of any two of the three primary colors to form a single two-color light emitting device, the corresponding organic layer can emit a light source of a corresponding color. Further, combined with the corresponding color filter layer and combined with a monochrome display device, a full color display can be realized, and the display rate of the panel is further improved.

Above are only embodiments of the disclosure is not patented and therefore limit the scope of the disclosure, the use of any content of the present specification and drawings made equivalent or equivalent structural transformation process, either directly or indirectly related to the use of other technologies areas are included in the same way the scope of the patent protection of the disclosure.

What is claimed is:

1. A full color display device, comprising:
a first electrode layer formed on a first substrate;
a light emitting layer formed on the first electrode layer and comprising:
a first light emitting layer, comprising luminescent materials of a first color and a second color, and
a second light emitting layer disposed at intervals and comprising a luminescent material of a third color; wherein the first color, the second color, and the third color constitute three primary colors, and the luminescent materials are one of a fluorescent luminescent material or a phosphorescent luminescent material;
a second electrode layer formed on the light emitting layer;
a color filter layer formed on the second electrode layer at a position corresponding to the first light emitting layer and comprising a first filter layer and a second filter layer disposed at intervals; wherein the first filter layer and the second filter layer correspond to the colors of the luminescent materials of the first light emitting layer; and
an encapsulation layer arranged on the second electrode layer.

2. The full color display device according to claim 1, wherein the color filter layer is formed between the second electrode layer and the encapsulation layer.

3. The full color display device according to claim 1, wherein the encapsulation layer is formed between the color filter layer and the second electrode layer.

4. The full color display device according to claim 1, further comprising a second substrate, and the color filter layer is formed on the second substrate.

5. The full color display device according to claim 1, wherein the encapsulation layer comprises a first encapsulation layer, a second encapsulation layer, and a third encapsulation layer, the first encapsulation layer and the third encapsulation layer are inorganic layers, and the second encapsulation layer is an organic layer.

6. The full color display device according to claim 1, further comprising a first common organic layer and a second common organic layer, wherein the first common organic layer is formed between the first substrate and the first electrode layer, and the second common organic layer is formed between the light emitting layer and the second electrode layer.

7. A full color display device, comprising:
a first electrode layer formed on a first substrate;
an light emitting layer formed on the first electrode layer and comprising:
a first light emitting layer, comprising luminescent materials of a first color and a second color, and
a second light emitting layer disposed at intervals and comprising a luminescent material of a third color; wherein the first color, the second color, and the third color constitute three primary colors;
a second electrode layer formed on the light emitting layer; and
a color filter layer formed on the second electrode layer at a position corresponding to the first light emitting layer, wherein the color filter layer comprises a first filter layer and a second filter layer disposed at intervals, and the first filter layer and the second filter layer correspond to the colors of the luminescent materials of the first light emitting layer.

8. The full color display device according to claim 7, further comprising an encapsulation layer arranged on the second electrode layer.

9. The full color display device according to claim 8, wherein the color filter layer is formed between the second electrode layer and the encapsulation layer.

10. The full color display device according to claim 8, wherein the encapsulation layer is formed between the color filter layer and the second electrode layer.

11. The full color display device according to claim 8, further comprising a second substrate, and the color filter layer is formed on the second substrate.

12. The full color display device according to claim 8, wherein the encapsulation layer comprises a first encapsulation layer, a second encapsulation layer, and a third encapsulation layer, the first encapsulation layer and the third encapsulation layer are inorganic layers, and the second encapsulation layer is an organic layer.

13. The full color display device according to claim 7, wherein the luminescent materials are one of a fluorescent luminescent material or a phosphorescent luminescent material.

14. The full color display device according to claim 7, further comprising a first common organic layer and a second common organic layer, wherein the first common organic layer is formed between the first substrate and the first electrode layer, and the second common organic layer is formed between the light emitting layer and the second electrode layer.

15. A manufacturing method of a full color display device, comprising:
forming a first electrode layer on the first substrate;
forming a light emitting layer comprising a first light emitting layer and a second light emitting layer on the first electrode layer, wherein the first light emitting layer comprises luminescent materials of a first color and a second color, the second light emitting layer comprises a luminescent material of a third color, and the first color, the second color, and the third color constitute three primary colors;
forming a second electrode layer on the light emitting layer; and
forming a color filter layer on the second electrode layer at a position corresponding to the first light emitting layer, wherein the color filter layer comprises a first filter layer and a second filter layer disposed at intervals, and the first filter layer and the second filter layer correspond to colors of the luminescent materials of the first light emitting layer.

16. The manufacturing method of a full color display device according to claim 15, wherein the manufacturing method further comprises:
forming an encapsulation layer on the second electrode layer.

17. The manufacturing method of a full color display device according to claim 15, wherein the luminescent materials are one of a fluorescent luminescent material or a phosphorescent luminescent material.
